(19) United States
(12) Patent Application Publication
(10) Pub. No.: US 2024/0334732 A1
(43) Pub. Date: Oct. 3, 2024

(54) LIGHT-EMITTING ELEMENT, LIGHT-EMITTING APPARATUS, AND DISPLAY APPARATUS

(71) Applicant: SHARP KABUSHIKI KAISHA, Sakai City, Osaka (JP)

(72) Inventor: KENJI KIMOTO, Sakai City, Osaka (JP)

(21) Appl. No.: 18/573,678

(22) PCT Filed: Aug. 16, 2021
(86) PCT No.: PCT/JP2021/029871

§ 371 Date: Dec. 22, 2023

(51) Int. Cl. H10K 50/17; H10K 50/82; H10K 102/00

(52) U.S. Cl. CPC H10K 50/171; H10K 50/82; H10K 2102/351

(57) ABSTRACT

In a light-emitting element, an electron affinity of an electron injection layer is greater than a work function of a cathode, and is greater than an electron affinity of an electron transport layer. The cathode has a metal layer containing first metal atoms arranged in a region in contact with an intermediate layer. The intermediate layer includes a region in contact with the metal layer of the cathode, and contains in the region: second metal atoms an element of which is equal to an element of the first metal atoms; and oxygen atoms.

### TECHNICAL FIELD

The disclosure relates to a light-emitting element in which a cathode, an intermediate layer, an electron injection layer, an electron transport layer, a light-emitting layer, and an anode are provided in the stated order. The disclosure also relates to a light-emitting apparatus and a display apparatus.

### BACKGROUND ART

A known quantum-dot light-emitting diode includes a light-emitting layer containing quantum dots (Patent Document 1). Patent Document 1 discloses a light-emitting element as an example of a quantum-dot light-emitting diode.

### CITATION LIST

### Patent Literature

[Patent Document 1] Japanese Unexamined Patent Application Publication (Translation of PCT Application) No. 2012-533156

### SUMMARY

### Technical Problem

In order to improve light emission efficiency of a light-emitting element including a light-emitting layer containing quantum dots, it is necessary to hold balance between amounts of electrons and holes to be injected into the light-emitting layer. Patent Document 1 is silent regarding how to freely control the balance between the amounts of electrons and holes to be injected into the light-emitting layer.

An aspect of the disclosure is set out to provide a light-emitting element, a light-emitting apparatus, and a display apparatus all of can emit light with high efficiency.

### Solution to Problem

In order to solve the above problem, a light-emitting element according to an aspect of the disclosure includes: a cathode; an intermediate layer; an electron injection layer; an electron transport layer; a light-emitting layer; and an anode, all of which are provided in a stated order. An electron affinity of the electron injection layer is greater than a work function of the cathode, and is greater than an electron affinity of the electron transport layer. The cathode has a metal layer containing first metal atoms arranged in a region in contact with the intermediate layer. The intermediate layer includes a region in contact with the metal layer of the cathode, and contains in the region: second metal atoms an element of which is equal to an element of the first metal atoms; and oxygen atoms.

In order to solve the above problem, a light-emitting apparatus according to an aspect of the disclosure includes a plurality of the light-emitting elements according to an aspect of the disclosure. At least two of the plurality of light-emitting elements have different emission wavelengths, and electron injection layers of the at least two light-emitting elements have different thicknesses.

In order to solve the above problem, a display apparatus according to an aspect of the disclosure includes a plurality of the light-emitting elements according to an aspect of the disclosure. One of the plurality of light-emitting elements emits light an emission spectrum of which has a peak wavelength of 430 nm or more and 485 or less. An other one of the plurality of light-emitting elements emits light an emission spectrum of which has a peak wavelength of 500 nm or more and 565 nm or less. Still an other one of the plurality of light-emitting elements emits light an emission spectrum of which has a peak wavelength of 620 nm or more and 770 nm or less. An electron injection layer of the one of the plurality of light-emitting elements is thicker than an electron injection layer of the other one of the plurality of light-emitting elements. The electron injection layer of the other one of the plurality of light-emitting elements is thicker than an electron injection layer of still the other one of the plurality of light-emitting elements.

### Advantageous Effect of Disclosure

An aspect of the disclosure can increase light emission efficiency of a light-emitting element, a light-emitting apparatus, and a display apparatus.

### BRIEF DESCRIPTION OF DRAWINGS

FIG. 1 is a cross-sectional view of a light-emitting element according to a first embodiment.

FIG. 2 is a schematic energy band diagram illustrating an operation of the light-emitting element.

FIG. 3 is an other schematic energy band diagram illustrating an operation of the light-emitting element.

FIG. 4 is a cross-sectional view of a light-emitting element according to a comparative example.

FIG. 5 is a graph showing light emission efficiency of the light-emitting element according to the first embodiment and light emission efficiency of the light-emitting element according to the comparative example.

FIG. 6 is a cross-sectional view of a light-emitting element according to a second embodiment.

FIG. 7 is a cross-sectional view of a light-emitting apparatus according to a third embodiment.

### DESCRIPTION OF EMBODIMENTS

### First Embodiment

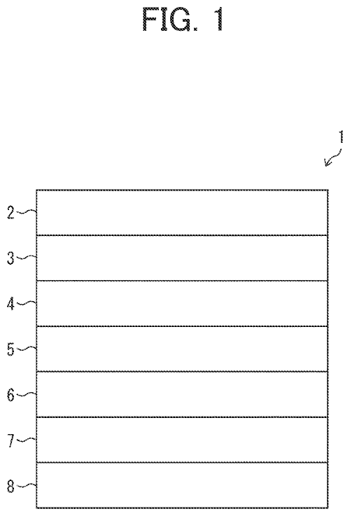

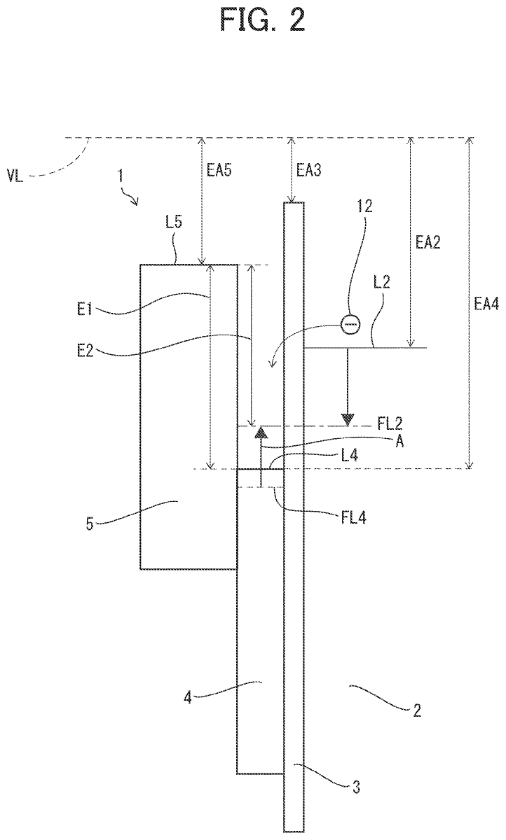

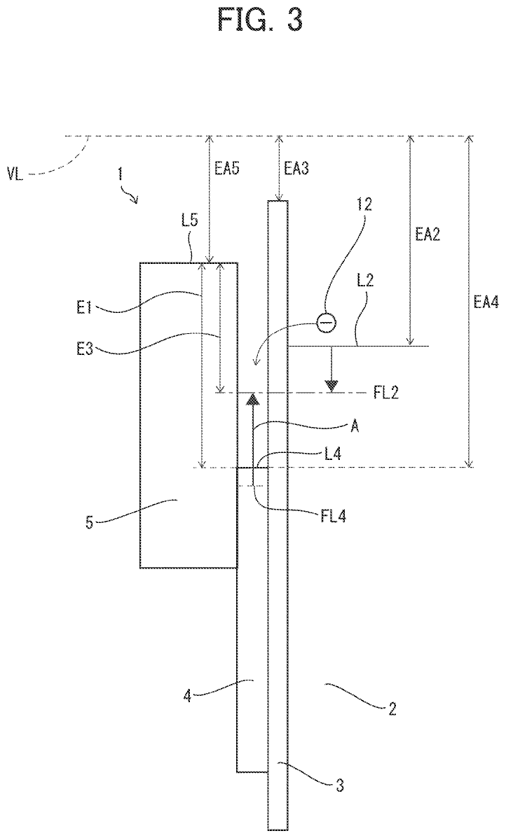

FIG. 1 is a cross-sectional view of a light-emitting element 1 according to a first embodiment. FIG. 2 is a schematic energy band diagram illustrating an operation of the light-emitting element 1. FIG. 3 is an other schematic energy band diagram illustrating an operation of the light-emitting element 1.

The light-emitting element 1 illustrated in FIG. 1 includes: a cathode 2; an intermediate layer 3; an electron injection layer (EIL) 4; an electron transport layer (ETL) 5; a light-emitting layer 6; a hole transport layer (HTL) 7; and anode 8, all of which are provided in the stated order.

FIGS. 2 and 3 are schematic energy band diagrams of the light-emitting element 1 in a flat-band condition. Note that FIGS. 2 and 3 omit illustrations of the light-emitting layer 6, the hole transport layer 7, and the anode 8.

As illustrated in FIG. 2, an electron affinity EA4 of the electron injection layer 4 is greater than a work function EA2 of the cathode 2. Here, the electron affinity EA4 is an absolute value of an energy difference between a vacuum level VL and an energy level L4 at a conduction band minimum of the electron injection layer 4 (hereinafter, the energy difference is an absolute value of the energy difference). The work function EA2 is an energy difference between the vacuum level VL and a Fermi level L2 of the cathode 2. That is, in FIG. 2, the energy level L4 at the conduction band minimum of the electron injection layer 4 is positioned below the Fermi level L2 of the cathode 2. Furthermore, the electron affinity EA4 of the electron injection layer 4 is greater than an electron affinity EA5 of the electron transport layer 5. Here, the electron affinity EA5 is an energy difference between the vacuum level VL and an energy level L5 at a conduction band minimum of the electron transport layer 5.

The cathode 2 has a metal layer containing first metal atoms arranged in a region in contact with the intermediate layer 3. The cathode 2 and the metal layer may coincide with each other. The intermediate layer 3 is disposed in a region in contact with the cathode 2, and contains: second metal atoms an element of which is equal to an element of the first metal atoms; and oxygen atoms. The second metal atoms and the oxygen atoms are provided in the region in contact at least with the cathode 2. Furthermore, the intermediate layer 3 is preferably disposed in a region in contact with the metal layer, and preferably contains: the second metal atoms the element of which is equal to the element of the first metal atoms; and the oxygen atoms. The second metal atoms and the oxygen atoms are provided in the region in contact with the metal layer.

The intermediate layer 3 may contain an oxide of the second metal atoms. Furthermore, the intermediate layer 3 may be formed of the oxide of the second metal atoms.

As illustrated in FIGS. 2 and 3, an electron affinity EA3 of the intermediate layer 3 may be smaller than the work function EA2 of the cathode 2, and may be smaller than the electron affinity EA5 of the electron transport layer 5. Here, the electron affinity EA3 is an energy difference between the vacuum level VL and an energy level at a conduction band minimum of the intermediate layer 3. Such features can effectively reduce formation of a trap level between the cathode 2 and the electron injection layer 4.

Note that FIGS. 2 and 3 show an example in which the work function EA2 of the cathode 2, the electron affinity EA3 of the intermediate layer 3, and the electron affinity EA5 of the electron transport layer 5 satisfy, but not limited to, the above relationships. For example, FIGS. 2 and 3 show that the intermediate layer 3 is a composition of such an insulator as Al₂O₃, and has a band gap. However, the presence or absence of the band gap would be unknown, depending on the composition of the intermediate layer 3; that is, for example, the second metal atoms are slightly oxidized.

Furthermore, as will be described later, if the composition of the intermediate layer 3 changes within the intermediate layer 3, the example in FIGS. 2 and 3 would be different and the conduction band minimum, the valence band minimum, and the band gap could change together with the change of the composition.

A number density of the second metal atoms in an end portion of the intermediate layer 3 at the cathode 2 may be higher than a number density of the second metal atoms in an end portion of the intermediate layer 3 at the electron injection layer 4. Furthermore, the number density of the second metal atoms in the intermediate layer 3 may gradually decrease from the end portion at the cathode 2 toward the end portion at the electron injection layer 4. Such features can effectively reduce formation of a trap level between the cathode 2 and the electron injection layer 4. Moreover, the intermediate layer 3 preferably has a region (alternatively, a spot or a point) in which a ratio of the number density of the second metal atoms to a number density of the oxygen atoms is 0.3 or more and 0.8 or less, and, more preferably, 0.4 or more and 0.5 or less. Such features can more effectively reduce formation of a trap level between the cathode 2 and the electron injection layer 4.

The electron injection layer 4 preferably contains Mo atoms or W atoms. The electron injection layer 4 more preferably further contains oxygen atoms; that is, the electron injection layer 4 preferably contains a Mo oxide or a W oxide.

The electron injection layer 4 has a thickness of preferably 0.1 nm or more and 20 nm or less, and, more preferably, 0.3 nm or more and 3 nm or less.

The electron injection layer 4 may be shaped into islands or particles.

The intermediate layer 3 has a thickness of preferably 0.1 nm or more and 2 nm or less, and, more preferably, 0.3 nm or more and 1 nm or less. Such a feature allows the electrons to move from the cathode 2, tunnel through the intermediate layer 3, and come to the electron injection layer 4.

The electron transport layer 5 preferably contains Zn atoms, a Zn oxide, and nanoparticles. These nanoparticles preferably contain Zn atoms and oxygen atoms.

The first metal atoms of the cathode 2 and the second metal atoms of the intermediate layer 3 are preferably made of aluminum.

The light-emitting layer 6 preferably contains a quantum dot phosphor.

The intermediate layer 3 and the electron injection layer 4 may be in contact with each other.

As can be seen, the light-emitting element 1 according to this embodiment includes: the cathode 2; the anode 8; the light-emitting layer 6 provided between the cathode 2 and the anode 8; the electron transport layer 5 provided between the cathode 2 and the light-emitting layer 6; the electron injection layer 4 provided between the cathode 2 and the electron transport layer 5; and the intermediate layer 3 provided between the cathode 2 and the electron injection layer 4, and brought into contact with the cathode 2. The electron injection layer 4 contains Mo atoms or W atoms. The cathode 2 includes the metal layer containing the first metal atoms. The metal layer is provided in a region in contact with the intermediate layer 3. The intermediate layer 3 contains the second metal atoms and the oxygen atoms in a region in contact with the cathode 2. The first metal atoms and the second metal atom are made of the same element.

The cathode 2 is made of, for example, Al. In such a case, the first metal atoms and the second metal atoms are Al. Al has a work function of 4.2 eV.

The electron injection layer 4 may be formed of, for example, molybdenum oxide (e.g., MoO₃), tungsten oxide (e.g., WO₃), and a mixture or a solid solution of molybdenum oxide and tungsten oxide. Note that these composition formulas are only examples, and shall not be limited to such examples. The electron injection layer 4 can be deposited by such techniques as vapor deposition and coating. Note that each of the materials has an electron affinity as follows: molybdenum oxide with 6 eV, tungsten oxide with 6 eV, and the mixture or the solid solution of molybdenum oxide and tungsten with 6 eV.

The electron transport layer 5 can be formed of, for example, zinc oxide (e.g., ZnO), Mg-doped zinc oxide (also referred to as ZnMgO), Al-doped zinc oxide (also referred to as AZO), B-doped zinc oxide (e.g., B-doped ZnO), and titanium oxide (e.g., TiO₂). Note that these composition formulas are only examples, and shall not be limited to such examples. The electron transport layer 5 may be formed of nanoparticles. The electron transport layer 5 can be deposited by such techniques as vapor deposition and coating. Note that each of the materials has an electron affinity as follows: zinc oxide with 4.4 eV, and titanium oxide with 4.0 eV. If zinc oxide additionally contains any one or more of Mg, Al, and B, the electron affinity is smaller than 4.4 eV. Furthermore, if titanium oxide additionally contains any one or more of Mg, Al, and B, the electron affinity is smaller than 4.0 eV.

The light-emitting layer 6 is an electroluminescence (EL) layer. The light-emitting layer 6 contains a quantum dot phosphor.

The hole transport layer 7 can be formed of, for example, NiO, Li-doped NiO, PEDOT: PSS, PVK, TFB, and TPD. The hole transport layer 7 may be formed as a mixture or a multilayer stack of two or more of these materials.

The anode 8 can be formed of, for example, ITO, IZO, FTO, In₂O₃, SnO₂, and ZnO.

Each of the layers of the light-emitting element 1 may be deposited by a known technique.

The light-emitting element 1 according to the first embodiment includes: the electron injection layer 4 formed between the cathode 2 and the electron transport layer 5, and containing molybdenum oxide (e.g., MoO₃) or tungsten oxide (e.g., WO₃); and the intermediate layer 3 formed between the cathode 2 and the electron injection layer 4.

If the cathode 2 contains aluminum, the intermediate layer 3 contains aluminum atoms and oxygen atoms in at least a portion of a region in contact with the cathode 2. The intermediate layer 3 contains, for example, aluminum oxide. Furthermore, the intermediate layer 3 may be made of aluminum oxide. The intermediate layer 3 can reduce formation of a trap level between the cathode 2 and the electron injection layer 4. Such a feature can control the height of an electron injection barrier.

Because the intermediate layer 3 is sufficiently thin for electrons to tunnel through, the cathode 2 and the electron injection layer 4 are in electrical contact with each other. The intermediate layer 3 does not have to be formed continuously in the form of a uniform film. The intermediate layer 3 may be shaped into islands separated from each other and scattered. The intermediate layer 3 shaped into islands can achieve an advantageous effect of reducing formation of a trap level between the cathode 2 and the electron injection layer 4. Note that the intermediate layer 3 is formed continuously in the form of a uniform film, which is more preferable because the continuously formed intermediate layer 3 can achieve the advantageous effects of the intermediate layer 3 among the advantageous effects of the disclosure.

The intermediate layer 3 can be formed by, but not limited to, such techniques as vapor deposition, sputtering, and coating. Alternatively, the intermediate layer 3 may be formed by a known technique.

Furthermore, the number density of the second metal atoms in the intermediate layer 3 may gradually decrease from the end portion at the cathode 2 toward the end portion at the electron injection layer 4. Moreover, the number density of the second metal atoms in an end portion of the intermediate layer 3 at the cathode 2 may be higher than the number density of the second metal atoms in an end portion of the intermediate layer 3 at the electron injection layer 4. If the intermediate layer 3 is formed by, for example, vapor deposition or sputtering, an amount of oxygen (a partial pressure of oxygen) in a film-depositing chamber is controlled so that the amount of oxygen in the film-depositing chamber gradually decreases as the deposition of the intermediate layer 3 progresses. Thanks to the control, the intermediate layer 3 can be deposited to have the above composition. The technique to deposit the intermediate layer 3 shall not be limited to such a technique. A known technique may be used to deposit the intermediate layer 3.

An electron affinity (6 eV) of molybdenum oxide and tungsten oxide contained in the electron injection layer 4 is significantly greater than an electron affinity (approximately 3.4 to 4.4 eV) of a material (e.g., ZnO, TiO₂, and ZnMgO) typically used for the electron transport layer 5. Hence, as illustrated in FIG. 2, the energy level L4 at the conduction band minimum of the electron injection layer 4 is significantly lower than the energy level L5 at the conduction band minimum of the electron transport layer 5. As a result, between the electron transport layer 5 and the electron injection layer 4, an electron injection barrier is formed to have a large energy difference E1.

Whereas, if the electron injection layer 4 and the cathode 2 that contains, for example, Al are in electrical contact with each other, as illustrated in FIG. 2, electrons 12 move from the cathode 2 through the intermediate layer 3 to the electron injection layer 4. As a result, the Fermi level L2 of the cathode 2 falls and a Fermi level FL4 of the electron injection layer 4 rises, so that the Fermi level L2 of the cathode 2 and the Fermi level FL4 of the electron injection layer 4 match at a Fermi level FL2.

Here, the electrons 12 moving from the cathode 2 to the electron injection layer 4 sequentially fill an empty energy level of the conduction band of the electron injection layer 4 upwards from the energy level L4 at the conduction band minimum. Accordingly, as illustrated in FIGS. 2 and 3, the thinner the electron injection layer 4 is, the greater the Fermi level FL4 of the electron injection layer 4 moves in the direction of an arrow A in the schematic energy band diagrams illustrated in FIGS. 2 and 3. Accordingly, the Fermi level FL4 moves further upwards. The height of the electron injection barrier between the electron transport layer 5 and the electron injection layer 4 represents an energy difference (i.e., E2 in FIGS. 2 and E3 in FIG. 3) between the energy level L5 at the conduction band minimum of the electron transport layer 5 and the Fermi level FL2.

That is, as illustrated in FIGS. 2 and 3, the height (the energy difference E3) of the electron injection barrier between the electron transport layer 5 and the electron injection layer 4 when the electron injection layer 4 is formed relatively thin is smaller than the height (the energy difference E2) of the electron injection barrier between the electron transport layer 5 and the electron injection layer 4 when the electron injection layer 4 is formed relatively thick.

Hence, the height of the electron injection barrier between the electron injection layer 4 and the electron transport layer 5 can be controlled through the thickness of the electron injection layer 4. That is, as illustrated in FIG. 3, the thinner the electron injection layer 4 is, the smaller the height (the energy difference E3) of the electron injection barrier is. This promotes injection of the electrons into the electron transport layer 5. Whereas, as illustrated in FIG. 2, the thicker the electron injection layer 4 is, the greater the height (the energy difference E2) of the electron injection barrier is between the electron injection layer 4 and the electron transport layer 5. This reduces injection of the electrons into the transport layer 5.

As the electron injection layer 4 is thinner, the energy level of the conduction band of the electron injection layer 4 is more discrete because of the quantum effect. Thus, the energy level moves upwards in the schematic energy band diagrams (FIGS. 2 and 3). Hence, the thinner the electron injection layer 4 is, the more likely the Fermi level FL2 of the electron injection layer 4 moves upwards after the electrons have moved from the cathode 2 to the electron injection layer 4. Accordingly, the height (the energy difference E3 in FIG. 3) of the electron injection barrier becomes smaller between the electron transport layer 5 and the electron injection layer 4.

Thus, as to the light-emitting element 1 according to this embodiment, the amount of electrons to be injected into the light-emitting layer 6 can be controlled through control of the thickness of the electron injection layer 4. Such a feature can hold balance between the amounts of the electrons and the holes to be injected into the light-emitting layer 6, and improve light emission efficiency of the light-emitting element 1.

Note that if the intermediate layer 3 is not provided between the electron injection layer 4 and the cathode 2, an interface between the electron injection layer 4 and the cathode 2; that is, a semiconductor-metal interface, is likely to have a trap level, such as metal induced gap states (MIGS), formed in an energy position corresponding to the inside of the electron injection layer 4. In such a case, even if the cathode 2 and the electron injection layer 4 are in electrical contact, and the electrons move, the electrons are trapped in the trap level such that the Fermi level FL2 is pinned at the energy position within the band gap of the electron injection layer 4. Hence, if the intermediate layer 3 is not provided between the electron injection layer 4 and the cathode 2, the height of the electron injection barrier cannot be controlled as described above.

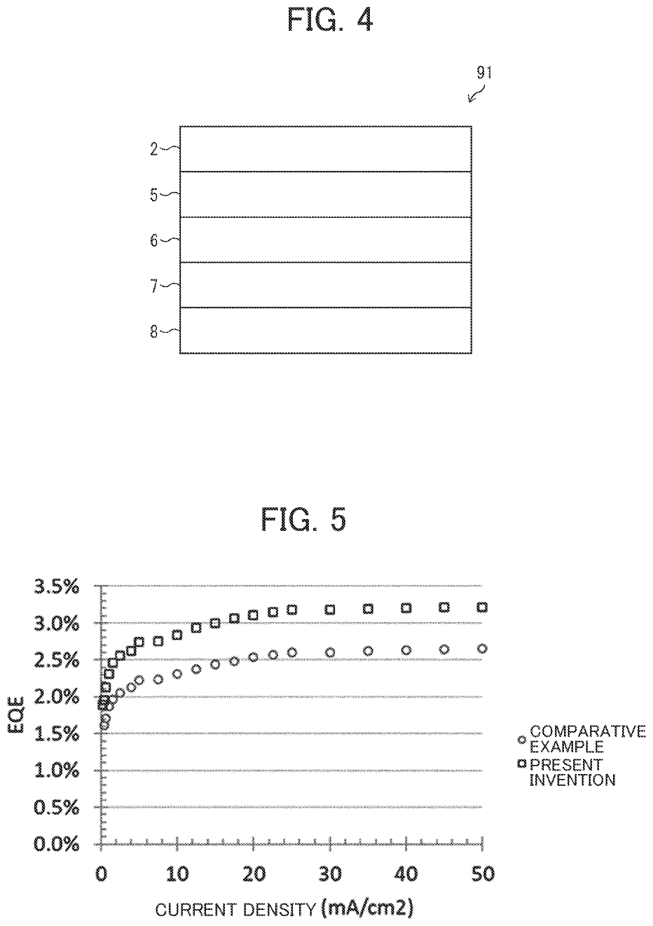

FIG. 4 is a cross-sectional view of a light-emitting element 91 according to a comparative example. The light-emitting element 91 omits the intermediate layer 3 and the electron injection layer 4. Otherwise, the light-emitting element 91 is the same in configuration as the light-emitting element 1.

Compared with the light-emitting element 91 of the comparative example illustrated in FIG. 4, the light-emitting element 1 of this embodiment illustrated in FIG. 1 further includes: the electron injection layer 4 made of MoO₃, having a thickness of, for example, 10 nm, and provided between the electron transport layer 5 and the cathode 2; and the intermediate layer 3 made of aluminum oxide, having a thickness of 0.8 nm, and provided between the electron injection layer 4 and the cathode 2. Through control of the thickness of the electron injection layer 4, the amount of electrons to be injected into the light-emitting layer 6 can be controlled, as described before. The electron injection layer 4 has a thickness of preferably 0.1 nm or more and 20 nm or less. Furthermore, the electron injection layer 4 may have a thickness of preferably 0.3 nm or more and 3 nm or less. In this case, the quantum effect is more remarkable, and the height of the electron injection barrier can be controlled more effectively. Moreover, the intermediate layer 3 has a thickness of preferably 0.1 nm or more and 2 nm or less, and, more preferably, 0.3 nm or more and 1 nm or less.

FIG. 5 is a graph showing light emission efficiency of the light-emitting element 1 according to the first embodiment and light emission efficiency of the light-emitting element 91 according to the comparative example. As shown in FIG. 5, the light-emitting element 1 of the first embodiment is higher in light emission efficiency than the light-emitting element 91 of the comparative example. This is probably because the intermediate layer 3 and the electron injection layer 4 are formed to control the amount of electrons to be injected into the light-emitting layer 6, such that the balance is held between the amounts of the electrons and the holes to be injected into the light-emitting layer 6.

The electron injection layer 4 does not have to be formed continuously in the form of a uniform film. The electron injection layer 4 may be shaped into islands separated from each other and scattered.

Between the layers of the light-emitting element 1, an other layer may further be formed. For example, between the light-emitting layer 6 and the hole transport layer 7, an other hole transport layer may be formed of, for example, polyvinyl carbazole (PVK), poly(9, 9-dioctyl-fluorene-co-N-4-butylphenyl-diphenylamine) (TFB), and triphenyldiamine (TPD).

The work function EA2 of the cathode 2 is preferably small. The work function EA2 of the cathode 2 is preferably 4.5 eV or less. The cathode 2 preferably contains Al, and, more preferably, contains Al atoms most.

The greater the difference is between the work function EA2 of the cathode 2 and the electron affinity EA4 of the electron injection layer 4, the greater a control range is of the height of the electron injection barrier and the greater a control range is of the amount of electrons to be injected into the light-emitting layer 6. The difference between the work function EA2 of the cathode 2 and the electron affinity EA4 of the electron injection layer 4 is preferably 0.8 eV or more, more preferably, 1.2 eV or more, and still more preferably, 1.7 eV or more.

Furthermore, the greater the difference is between the electron affinity EA5 of the electron transport layer 5 and the electron affinity EA4 of the electron injection layer 4, the greater the control range is of the height of the electron injection barrier and the greater the control range is of the amount of electrons to be injected into the light-emitting layer 6. The difference between the electron affinity EA5 of the electron transport layer 5 and the electron affinity EA4 of the electron injection layer 4 is preferably 1.0 eV or more, more preferably, 1.4 eV or more, and still more preferably, 1.8 eV or more.

The intermediate layer 3 preferably has an oxide containing Al. For example, aluminum oxide, Li-doped aluminum oxide, Mg-doped aluminum oxide, or Yb-doped aluminum oxide can be used as a material of the intermediate layer 3. Thanks to the intermediate layer 3, the height of the electron injection barrier is effectively controlled through the thickness of the electron injection layer 4.

The intermediate layer 3 has a thickness of preferably 0.1 nm or more and 2 nm or less, and, more preferably, 0.3 nm or more and 1 nm or less. An excessively thin intermediate layer 3 is less likely to sufficiently exhibit the advantageous effect to reduce formation of a trap level. An excessively thick intermediate layer 3 blocks conduction of the electrons.

A composition ratio of MoO₃ contained in the electron injection layer 4 shall not be limited to Mo:O=1:3. Furthermore, for the electron injection layer 4, tungsten oxide (e.g., WO₃) may be used instead of MoO₃. Composition formulas such as MoO₃ and WO₃ are representative examples of composition ratios, and composition ratios of molybdenum oxide and tungsten oxide may be any given composition ratios.

The cathode 2 has a metal layer in a region in contact with the intermediate layer 3. The metal layer has a thickness of preferably 3 nm or more and 10 μm or less, more preferably, 5 nm or more and 300 nm or less, and still more preferably, 50 nm or more and 300 nm or less. An excessively thin cathode 2 makes it difficult to effectively control the height of the electron injection barrier. Furthermore, an excessively thick cathode 2 increases stress, and the performance of the light-emitting element 1 is likely to deteriorate. The cathode 2 has a sheet resistance of 1 Ω/sq. or less, and, more preferably, 0.1 Ω/sq. or less. Moreover, the cathode 2 is preferably not transparent to light. The cathode 2 has a transmittance of preferably 1% or less, and more preferably, 0%.

### Second Embodiment

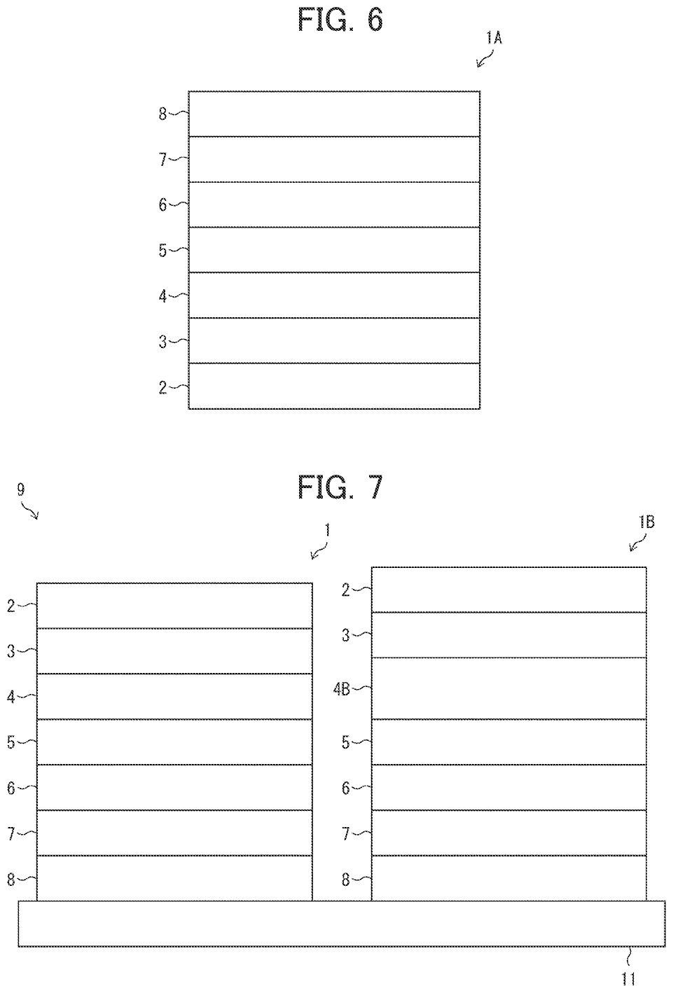

FIG. 6 is a cross-sectional view of a light-emitting element 1A according to a second embodiment. Identical reference signs are used to denote identical constituent elements between this embodiment and the previous embodiment. Such constituent elements will not be elaborated upon repeatedly.

The light-emitting element 1A of the second embodiment is the light-emitting element 1 of the first embodiment whose layers are stacked in the reverse order. Hence, the stacking order of the layers of the light-emitting element 1A may be the reverse order of the layers of the light-emitting element 1 according to the first embodiment. Thus, the light-emitting element 1A also achieves the same advantageous effects as those of the light-emitting element 1.

### Third Embodiment

FIG. 7 is a cross-sectional view of a light-emitting apparatus 9 according to a third embodiment. Identical reference signs are used to denote identical constituent elements between this embodiment and the previous embodiments. Such constituent elements will not be elaborated upon repeatedly.

The light-emitting apparatus 9 includes: a glass substrate 11; and at least two light-emitting elements 1 and 1B formed on the glass substrate 11. The light-emitting element 1 has the electron injection layer 4. The light-emitting element 1B has an electron injection layer 4B.

The light-emitting elements 1 and 1B have different emission wavelengths, and the electron injection layers 4 and 4B have different thicknesses.

The emission wavelength of the light-emitting element 1B is longer than the emission wavelength of the light-emitting element 1. The electron injection layer 4B of the light-emitting element 1B is thicker than the electron injection layer 4 of the light-emitting element 1.

Furthermore, the display apparatus may have three or more light-emitting elements. Among the three or more light-emitting elements, at least three light-emitting elements may have different emission wavelengths (peak wavelengths of emission spectra). The electron injection layers of the at least three light-emitting elements may have different thicknesses.

Moreover, the display apparatus may have three or more light-emitting elements. Among the three or more light-emitting elements, at least three light-emitting elements may have different emission wavelengths (peak wavelengths of emission spectra). The electron injection layers of the at least three light-emitting elements may be thicker in the order of the emission wavelengths.

In addition, the display apparatus can have three or more light-emitting elements. One of the three or more light-emitting elements can emit a red light, an other one of the three or more light-emitting elements can emit a green light, and still an other one of the three or more light-emitting elements can emit a blue light. An electron injection layer of one of the three or more light-emitting elements can be thicker than an electron injection layer of an other one of the three or more light-emitting elements. The electron injection layer of the other one of the three or more light-emitting elements can be thicker than an electron injection layer of a still an other one of the three or more light-emitting elements.

Furthermore, the display apparatus may have three or more light-emitting elements. One of the three or more light-emitting elements may be a red light-emitting element that emits a red light. An other one of the three or more light-emitting elements may be a green light-emitting element that emits a green light. Still an other one of the three or more light-emitting elements may be a blue light-emitting element that emits a blue light. An electron injection layer of the red light-emitting element may be thicker than the green light-emitting element. An electron injection layer of the green light-emitting element may be thicker than an electron injection layer of the blue light-emitting element.

Note that red, green, and blue mean that the peak wavelength of the emission spectrum is 430 nm or more and 485 nm or less for red, 500 nm or more and 565 nm or less for green, and 620 nm or more and 770 nm or less for blue.

The electron injection layers (EILs) 4 and 4B contain molybdenum oxide. Alternatively, the EILs 4 and 4B may contain tungsten oxide, or may be an oxide containing at least Mo and/or W.

If the light-emitting element 1 has an emission wavelength λ1 (nm) and the light-emitting element 1B has an emission wavelength λ2 (nm) (i.e., λ1<λ2), the electron injection layer 4B of the light-emitting element 1B is different in thickness from the electron injection layer 4 of the light-emitting element 1.

As to the light-emitting elements 1 and 1B having different emission wavelengths, at least the materials of the respective light-emitting layers 6 are different. So are the optimum amounts of electrons to be injected into the respective light-emitting layers 6. The light-emitting elements 1 and 1B of this embodiment can control the amount of electrons to be injected through the thicknesses of the electron injection layers 4 and 4B. Hence, the two light-emitting elements 1 and 1B having different emission wavelengths respectively include the electron injection layers 4 and 4B having different thicknesses. Thanks to such a feature, a suitable amount of electrons can be injected for each of the light-emitting elements 1 and 1B. As a result, each of the light-emitting elements 1 and 1B can emit light with suitable light emission efficiency.

If the light-emitting element 1 has an emission wavelength λ1 (nm) and the light-emitting element 1B has an emission wavelength λ2 (nm) (i.e., λ1<λ2), the electron injection layer 4B of the light-emitting element 1B is preferably thicker than the electron injection layer 4 of the light-emitting element 1.

If a relationship of λ1<λ2 holds, in the schematic energy band diagrams, the energy level at the conduction band minimum of the light-emitting layer 6 in the light-emitting element 1 tends to be positioned above the energy level at the conduction band minimum of the light-emitting layer 6 in the light-emitting element 1B. That is why the amount of electrons to be injected is likely to decrease. In the light-emitting apparatus 9 according to this embodiment, the electron injection layer 4B of the light-emitting element 1B is thicker than the electron injection layer 4 of the light-emitting element 1. Thanks to such a feature, a suitable amount of electrons can be injected for each of the light-emitting elements 1 and 1B. As a result, each of the light-emitting elements 1 and 1B can emit light with suitable light emission efficiency.

As seen in the second embodiment, the layers of the light-emitting elements 1 and 1B may be stacked in the reverse order. Even if the layers are stacked in the reverse order, the light-emitting elements 1 and 1B achieve the same advantageous effects.

The disclosure shall not be limited to the embodiments described above, and can be modified in various manners within the scope of claims. The technical aspects disclosed in different embodiments are to be appropriately combined together to implement an other embodiment. Such an embodiment shall be included within the technical scope of the disclosure. Moreover, the technical aspects disclosed in each embodiment may be combined to achieve a new technical feature.

1. A light-emitting element, comprising:
a cathode; an intermediate layer; an electron injection layer; an electron transport layer; a light-emitting layer; and an anode, all of which are provided in a stated order,
wherein an electron affinity of the electron injection layer is greater than a work function of the cathode, and is greater than an electron affinity of the electron transport layer,
the cathode has a metal layer containing first metal atoms arranged in a region in contact with the intermediate layer, and
the intermediate layer includes a region in contact with the metal layer of the cathode, and contains in the region: second metal atoms an element of which is equal to an element of the first metal atoms; and oxygen atoms.

2. The light-emitting element according to claim 1,
wherein the electron injection layer contains Mo atoms or W atoms.

3. The light-emitting element according to claim 2,
wherein the electron injection layer further contains oxygen atoms.

4. The light-emitting element according to claim 2,
wherein the electron injection layer contains a Mo oxide or a W oxide.

5. The light-emitting element according to claim 1,
wherein an absolute value of a difference between the work function of the cathode and the electron affinity of the electron injection layer is 0.8 eV or more.

6. The light-emitting element according to claim 1,
wherein an absolute value of a difference between the electron affinity of the electron injection layer and the electron affinity of the electron transport layer is 1.0 eV or more.

7. The light-emitting element according to claim 1,
wherein the electron injection layer has a thickness of 0.1 nm or more and 20 nm or less.

8. The light-emitting element according to claim 7,
wherein the electron injection layer has a thickness of 0.3 nm or more and 3 nm or less.

9. The light-emitting element according to claim 1,
wherein the electron injection layer is shaped into islands or particles.

10. The light-emitting element according to claim 9,
wherein the intermediate layer has a thickness of 0.1 nm or more and 2 nm or less.

11. The light-emitting element according to claim 10,
wherein the intermediate layer has a thickness of 0.3 nm or more and 1 nm or less.

12. The light-emitting element according to claim 1,
wherein the electron transport layer contains Zn atoms.

13. The light-emitting element according to claim 1,
wherein the electron transport layer contains a Zn oxide.

14. The light-emitting element according to claim 1,
wherein the electron transport layer contains nanoparticles.

15. The light-emitting element according to claim 14,
wherein the nanoparticles contain Zn atoms and oxygen atoms.

16. The light-emitting element according to claim 1,
wherein the first metal atoms and the second metal atoms are made of aluminum.

17. The light-emitting element according to claim 1,
wherein the light-emitting layer contains a quantum dot phosphor.

18. A light-emitting apparatus, comprising
a plurality of the light-emitting elements according to claim 1,
wherein at least two of the plurality of light-emitting elements have different emission wavelengths, and electron injection layers of the at least two light-emitting elements have different thicknesses.

19. The light-emitting apparatus according to claim 18,
wherein, of the at least two light-emitting elements, a light-emitting element having a long emission wavelength includes an electron injection layer thicker than an electron injection layer of a light-emitting element having a short emission wavelength.

20. A display apparatus, comprising
a plurality of the light-emitting elements according to claim 1,
wherein one of the plurality of light-emitting elements emits light an emission spectrum of which has a peak wavelength of 430 nm or more and 485 nm or less,
an other one of the plurality of light-emitting elements emits light an emission spectrum of which has a peak wavelength of 500 nm or more and 565 nm or less,
still an other one of the plurality of light-emitting elements emits light an emission spectrum of which has a peak wavelength of 620 nm or more and 770 nm or less,
an electron injection layer of the one of the plurality of light-emitting elements is thicker than an electron injection layer of the other one of the plurality of light-emitting elements, and
the electron injection layer of the other one of the plurality of light-emitting elements is thicker than an electron injection layer of still the other one of the plurality of light-emitting elements.
